(19) United States
(12) Patent Application Publication
(10) Pub. No.: US 2025/0072174 A1
(43) Pub. Date: Feb. 27, 2025

(54) LIGHT EMITTING SUBSTRATE, DISPLAY APPARATUS, SPLICING SCREEEN DISPLAY APPARATUS, AND METHOD OF OPERATING DISPLAY APPARATUS

(71) Applicants: BEIJING BOE DISPLAY TECHNOLOGY CO., LTD., Beijing (CN); BOE Technology Group Co., Ltd., Beijing (CN)

(72) Inventors: Wei Zhong, Beijing (CN); Haijun Shi, Beijing (CN); Changjia Fu, Beijing (CN); Qingshan Qu, Beijing (CN); Haiyan Wan, Beijing (CN)

(73) Assignees: BEIJING BOE DISPLAY TECHNOLOGY CO., LTD., Beijing (CN); BOE Technology Group Co., Ltd., Beijing (CN)

(21) Appl. No.: 18/729,115

(22) PCT Filed: Apr. 25, 2023
(86) PCT No.: PCT/CN2023/090634

§ 371 Date: Jul. 15, 2024

(51) Int. Cl. H01L 33/50; G09F 9/302; H01L 25/075; H01L 25/16

(52) U.S. Cl. CPC H01L 33/502; G09F 9/3026; H01L 25/0753; H01L 25/167; H01L 2933/0091

(57) ABSTRACT

A light emitting substrate is provided. The light emitting substrate includes light emitting elements of multiple types. The light emitting elements of different types are configured to emit light of a same color but different wavelength ranges. Light emitting elements of a respective type of the light emitting elements of multiple types are substantially evenly distributed in the light emitting substrate.

### TECHNICAL FIELD

The present invention relates to display technology, more particularly, to a light emitting substrate, a display apparatus, a splicing screen display apparatus, and a method of operating a display apparatus

### BACKGROUND

A mini-light emitting diode (mini-LED) refers to a light emitting diode having a size between 80 μm and 300 μm. Mini-LED may be used for self-luminous LED display, or as a backlight module of a display panel such as a liquid crystal display panel. Mini-LEDs achieve a higher resolution as compared to related light emitting diodes Compared with the traditional edge-lit light emitting diode backlight module. the direct-lit mini-LED backlight module can reduce the light mixing distance by a denser chip arrangement. thus achieving an ultra-thin backlight module. With proper local dimming control, Mini-LED can achieve better contrast and High-Dynamic Range (HDR) image display effect.

### SUMMARY

In one aspect, the present disclosure provides a light emitting substrate, comprising light emitting elements of multiple types; wherein the light emitting elements of different types are configured to emit light of a same color but different wavelength ranges: and light emitting elements of a respective type of the light emitting elements of multiple types are substantially evenly distributed in the light emitting substrate.

Optionally, the light emitting elements of different types are configured to emit light of a blue color but different wavelength ranges.

Optionally, a respective percentage of light emitting elements of the respective type in each of a plurality of areas of the light emitting substrate is substantially the same; and each area of the plurality of areas in the light emitting substrate includes at least 10 light emitting elements.

Optionally. the light emitting elements of the light emitting substrate are arranged in an array comprising rows and columns: and the light emitting elements of multiple types are alternately arranged in at least one row of the array.

Optionally, the light emitting elements of multiple types are alternately arranged in each row of the array.

Optionally, the light emitting elements of the light emitting substrate are arranged in an array comprising rows and columns: and the light emitting elements of multiple types are alternately arranged in at least one column of the array.

Optionally, the light emitting elements of multiple types are alternately arranged in each column of the array.

Optionally, the light emitting elements of the light emitting substrate are arranged in an array comprising rows and columns: and the light emitting elements of multiple types are alternately arranged in at least one row of the array and in at least one column of the array.

Optionally, the light emitting elements of multiple types are alternately arranged in each row of the array and in each column of the array

Optionally, the light emitting substrate comprises light emitting elements of N number of types. N being an integer equal to or greater than 2; and a percentage of light emitting elements of a n-th type in each of a plurality of areas in the light emitting substrate is substantially the same, 2≤n≤N.

Optionally, the light emitting substrate comprises light emitting elements of a first type and light emitting elements of a second type; wherein the light emitting elements of the first type and the light emitting elements of the second type are configured to emit a blue light.

Optionally, the light emitting elements of the first type are configured to emit a blue light having a wavelength in a range of 447 nm to 448 nm; and the light emitting elements of the second type are configured to emit a blue light having a wavelength in a range of 452 nm to 453 nm.

In another aspect. the present disclosure provides a display apparatus. comprising the light emitting substrate described herein. and a display panel configured to receive light emitted from the light emitting substrate.

Optionally, the display apparatus further comprises a color conversion laver: wherein the color conversion layer comprises: a plurality of color conversion blocks configured to convert light emitted from the light emitting substrate into a light of a different color; and a plurality of light transmissive blocks configured to allow the light emitted from the light emitting substrate to transmit through without color conversion.

Optionally, the display apparatus further comprises one or more driving circuits configured to adjust driving currents respectively provided to the light emitting elements of multiple types.

In another aspect, the present disclosure provides a splicing screen display apparatus, comprising a plurality of display units: wherein the plurality of display units comprise a plurality of display panels, and a plurality of light emitting substrates configured to provide light to the plurality of display panels: a respective display unit of the plurality of display units comprises a respective display panel of the plurality of display panels and a respective light emitting substrate of the plurality of light emitting substrates; and the plurality of display panels are spliced together to display an image: wherein the respective light emitting substrate comprises light emitting elements of multiple types: wherein the light emitting elements of different types are configured to emit light of a same color but different wavelength ranges: and light emitting elements of a respective type of the light emitting elements of multiple types are substantially evenly distributed in the light emitting substrate.

Optionally, the plurality of display units further include a plurality of color conversion layers configured to convert light emitted from the plurality of light emitting substrates. a respective display unit of the plurality of display units comprises a respective color conversion layer of the plurality of color conversion layers: the respective color conversion layer comprises: a plurality of color conversion blocks configured to convert a light emitted from the light emitting substrate into a light of a different color: and a plurality of light transmissive blocks configured to allow the light emitted from the light emitting substrate to transmit through without color conversion.

Optionally. the respective display unit further comprises one or more driving circuits configured to adjust driving currents respectively provided to the light emitting elements of multiple types: and the one or more driving circuits are configured to independently adjust driving currents, with respect to each type of the multiple types. provided to the light emitting elements of multiple types.

Optionally, the plurality of display units comprise driving circuits of multiple types: a respective display unit comprises a respective driving circuit of each type: driving currents in each of the plurality of display units are independently adjustable by the driving circuits of multiple types: and a color coordinate of light emitted from each of the plurality of display units are independently adjustable by the driving circuits of multiple types

In another aspect. the present disclosure provides a method of operating a display apparatus comprising a light emitting substrate and a display panel configured to receive light emitted from the light emitting substrate; wherein the light emitting substrate includes light emitting elements of multiple types: and light emitting elements of a respective type of the light emitting elements of multiple types are substantially evenly distributed in the light emitting substrate: wherein the method comprises to adjust driving currents respectively provided to the light emitting elements of multiple types; and driving the light emitting elements of different types to emit light of a same color but different wavelength ranges.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating the structure of a related display apparatus.

FIG. 2 is a schematic diagram illustrating the structure of a related splicing screen display apparatus.

FIG. 3 shows color difference observed in a related splicing screen display apparatus.

FIG. 4A shows an absorption spectrum of a green quantum-dots material.

FIG. 4B shows an absorption spectrum of a red quantum-dots material.

FIG. 4C shows a photoluminescence spectrum of a green quantum-dots material.

FIG. 4D shows a photoluminescence spectrum of a red quantum-dots material.

FIG. 5 shows light spectrums of light produced from a light emitting substrate and a color conversion layer in some embodiments according to the present disclosure.

FIG. 6 shows color coordinates of light produced from a light emitting substrate and a color conversion layer in some embodiments according to the present disclosure.

FIG. 7 illustrates color coordinate transition in some embodiments according to the present disclosure.

FIG. 8 is a schematic diagram illustrating the structure of a display apparatus in some embodiments according to the present disclosure.

FIG. 9 is a schematic diagram illustrating the structure of a light emitting substrate in some embodiments according to the present disclosure.

FIG. 10 is a schematic diagram illustrating the structure of a light emitting substrate in some embodiments according to the present disclosure.

FIG. 11 is a schematic diagram illustrating the structure of a light emitting substrate in some embodiments according to the present disclosure.

FIG. 12 is a schematic diagram illustrating the structure of a light emitting substrate in some embodiments according to the present disclosure.

FIG. 13A is a plan view of a light emitting substrate in some embodiments according to the present disclosure.

FIG. 13B is a cross-sectional view of a light emitting substrate in some embodiments according to the present disclosure.

FIG. 13C is a cross-sectional view of a light emitting substrate in some embodiments according to the present disclosure.

FIG. 14A is a schematic diagram illustrating the structure of a first color conversion block in some embodiments according to the present disclosure.

FIG. 14B is a schematic diagram illustrating the structure of a second color conversion block in some embodiments according to the present disclosure.

FIG. 14C is a schematic diagram illustrating the structure of a light transmissive block in some embodiments according to the present disclosure.

FIG. 15 is a schematic diagram illustrating the structure of a respective display unit in some embodiments according to the present disclosure.

FIG. 16 is a schematic diagram illustrating the structure of a splicing screen display apparatus in some embodiments according to the present disclosure.

FIG. 17 is a circuit diagram illustrating the structure of a respective pixel driving circuit in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed

Liquid crystal splicing screens have been developed, particularly in combination with mini-LED backlights. When mini-LED backlights are used in combination with the liquid crystal splicing screens, a high color gamut and high dynamic contrast ratio can be achieved with local dimming technology.

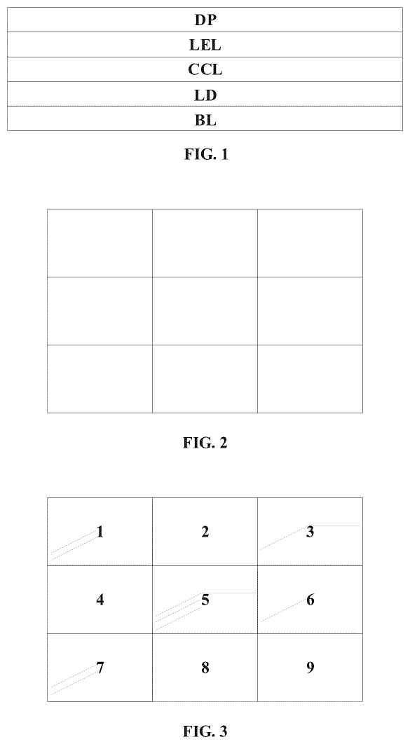

FIG. 1 is a schematic diagram illustrating the structure of a related display apparatus. Referring to FIG. 1, the display apparatus in some embodiments includes a backlight BL, a light diffusor LD on the back light BL, a color conversion layer CCL on a side of the light diffuser LD away from the backlight BL. a light enhancing layer LEL on a side of the color conversion layer CCL away from the backlight BL, and a display panel DP on a side of the light enhancing light LEL away from the backlight BL. In some embodiments, the display panel DP is a liquid crystal display panel. In some embodiments, the color conversion layer CCL is a quantum-dots color conversion layer including one or more quantum dots materials. Optionally. the color conversion layer CCL is a color conversion film. In some embodiments. the light enhancing layer LEL includes a dual brightness enhancement film. In some embodiments. the light enhancing layer LEL includes a prism layer including a plurality of prisms.

FIG. 2 is a schematic diagram illustrating the structure of a related splicing screen display apparatus. Referring to FIG. 2, the splicing screen display apparatus includes a plurality of display panels spliced together. The inventors of the present disclosure discover that color characteristics of light converted by the color conversion layer in the related display apparatus fluctuates by multiple factors, including compositions of quantum dots materials, materials of a barrier film used in the color conversion layer, amounts of adhesives used in the fabrication process, and coating uniformity. Because the related splicing screen display apparatus includes a plurality of display panels spliced together, and each of the display panels has its own color conversion layer. The differences among color characteristics of light converted by the color conversion layers in the plurality of display panels result in color differences among the plurality of display panels, particularly when the color conversion layers in the plurality of display panels are fabricated in different batches. FIG. 3 shows color difference observed in a related splicing screen display apparatus. Referring to FIG. 3. display panels 1, 3, 5, 6, and 7 exhibit a color shift toward yellow.

Accordingly, the present disclosure provides, inter alia, a light emitting substrate, a display apparatus, a splicing screen display apparatus, and a method of operating a display apparatus that substantially obviate one or more of the problems due to limitations and disadvantages of the related art. In one aspect, the present disclosure provides a light emitting substrate. In some embodiments, the light emitting substrate includes light emitting elements of multiple types Optionally, the light emitting elements of different types are configured to emit light of a same color but different wavelength ranges. Optionally, light emitting elements of a respective type of the light emitting elements of multiple types are substantially evenly distributed in the light emitting substrate.

The inventors of the present disclosure discover that light absorption of a color

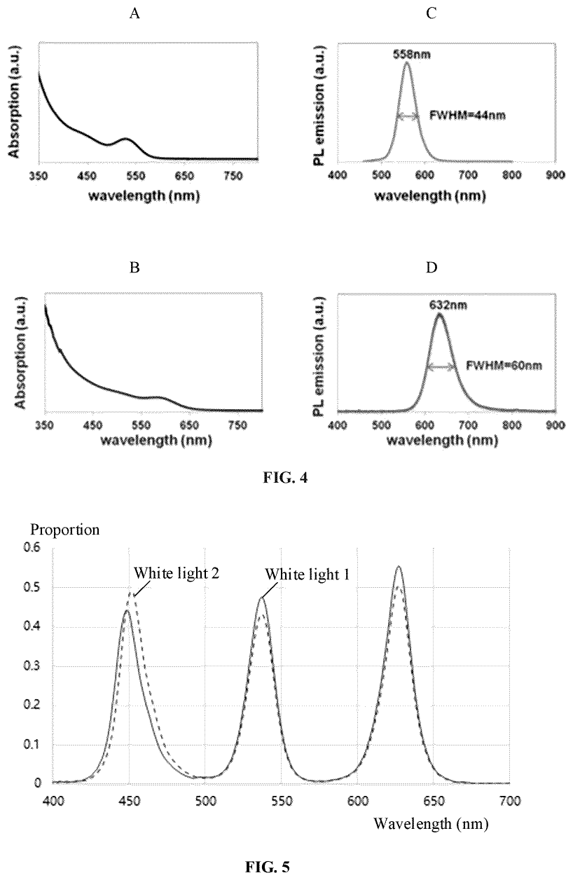

conversion material (e.g., a quantum-dots material) in the color conversion layer depends on a wavelength of the light (e.g., a blue light) irradiated on the color conversion material. FIG. 4A shows an absorption spectrum of a green quantum-dots material. Referring to FIG. 4A, light absorption of the green quantum-dots material depends on a wavelength of light (e g . . . a blue light) irradiated on the green quantum-dots material in the color conversion layer. The smaller the blue light wavelength. the higher the absorption and thus the green quantum-dots material excitation, leading to a converted light in which the color shifts towards green.

FIG. 4B shows an absorption spectrum of a red quantum-dots material. Referring to FIG. 4B. light absorption of the red quantum-dots material depends on a wavelength of light (e.g., a blue light) irradiated on the red quantum-dots material in the color conversion laver. The smaller the blue light wavelength, the higher the absorption and thus the red quantum-dots material excitation, leading to a converted light in which the color shifts towards green.

In some embodiments, the color conversion layer includes both the green quantum-dots material and the red quantum-dots material. The color conversion layer optionally further includes a plurality of light transmissive regions allowing the blue light to transmit through without color conversion. The red light converted by the red quantum-dots material. the green light converted by the green quantum-dots material, and the blue light transmitted through without color conversion intermix together to produce a white light. Referring to FIG. 4A and FIG. 4B. when a blue light of a relatively short wavelength is used for excitation of the quantum-dots materials, the white light produced by the color conversion layer has a color shift toward yellow. When a blue light of a relatively long wavelength is used for excitation of the quantum-dots materials, the white light produced by the color conversion layer has a color shift toward blue.

FIG. 4C shows a photoluminescence spectrum of a green quantum-dots material. Referring to FIG. 4C, the photoluminescence spectrum of the green quantum-dots material in one example has a peak wavelength of 558 nm, and a full width at half maximum of 44 nm. FIG. 4D shows a photoluminescence spectrum of a red quantum-dots material. Referring to FIG. 4D, the photoluminescence spectrum of the red quantum-dots material in one example has a peak wavelength of 632 nm, and a full width at half maximum of 60 nm.

FIG. 5 shows light spectrums of light produced from a light emitting substrate and a color conversion layer in some embodiments according to the present disclosure. Referring to FIG. 5. the solid line (white light 1) denotes a light spectrum of light produced from a light emitting substrate and a color conversion layer when a blue light of a relatively short wavelength is used for excitation of the quantum-dots materials in the color conversion layer: and the dotted line (white light 2) denotes a light spectrum of light produced from a light emitting substrate and a color conversion layer when a blue light of a relatively long wavelength is used for excitation of the quantum-dots materials in the color conversion layer. When the blue light of a relatively short wavelength is used for excitation of the quantum-dots materials in the color conversion layer. proportions of red light and green light in the white light spectrum increase (e.g., by 10%) whereas a proportion of the blue light in the white light spectrum decreases (e.g., by 10%). When the blue light of a relatively long wavelength is used for excitation of the quantum-dots materials in the color conversion layer, proportions of red light and green light in the white light spectrum decrease (e g., by 10%) whereas a proportion of the blue light in the white light spectrum increases (e.g., by 10%).

In some embodiments, a color coordinate of a light spectrum can be calculated according to:

$$x = X / ( X + Y + Z ) ; and y = Y * ( X + Y + Z ) ; \\ wherein X = {\int }_{380}^{780} φ ( λ ) * x ( λ ) d λ ; \\ Y = {\int }_{380}^{780} φ ( λ ) * y ( λ ) d λ ; and \\ Z = {\int }_{380}^{780} φ ( λ ) * z ( λ ) d λ ;$$

wherein φ(λ) stands for a light spectrum; and x(λ), y(λ), and z(λ) stand for tristimulus values.

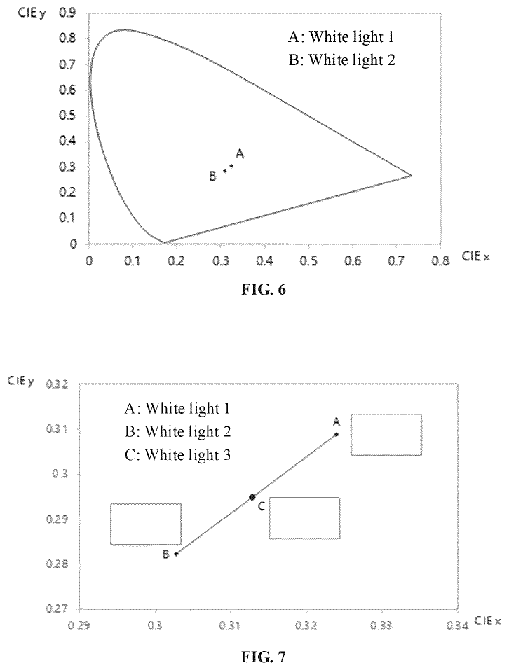

FIG. 6 shows color coordinates of light produced from a light emitting substrate and a color conversion layer in some embodiments according to the present disclosure. Referring to FIG. 6, the white light 1 (light produced from a light emitting substrate and a color conversion layer when a blue light of a relatively short wavelength is used for excitation of the quantum-dots materials in the color conversion layer) has a color coordinate corresponding to a color shift towards yellow; and the white light 2 (light produced from a light emitting substrate and a color conversion layer when a blue light of a relatively long wavelength is used for excitation of the quantum-dots materials in the color conversion layer) has a color coordinate corresponding to a color shift towards blue.

FIG. 7 illustrates color coordinate transition in some embodiments according to the present disclosure. Referring to FIG. 7. color coordinates of the white light 1 and the white light 2 are discussed above. White light 3 denotes a color coordinate of light produced from a light emitting substrate and a color conversion layer when a mixed blue light comprising a blue light of a relatively short wavelength and a blue light of a relatively long wavelength is used for excitation of the quantum-dots materials in the color conversion layer. As shown in FIG. 7, the color coordinate of the white light 3 is between color coordinates of the white light 1 and the white light 2. A color of the white light transitions from shifting yellow at point A to shifting blue at point B, as depicted in the accompanying rectangular shapes.

The inventors of the present disclosure discover that, by using a light emitting substrate having light emitting elements of multiple types (e.g., light emitting elements of the first type and light emitting elements of the second type), the light emitting substrate can produce a mixed light comprising light of multiple wavelength ranges (e.g., a mixed blue light comprising a blue light of a relatively short wavelength and a blue light of a relatively long wavelength). By adjusting driving currents respectively provided to the light emitting elements of multiple types (e.g., driving currents respectively provided to the light emitting elements of the first type and to the light emitting elements of the second type), proportions of light of multiple wavelength ranges in the mixed light (e.g., proportions of the blue light of the relatively short wavelength and the blue light of the relatively long wavelength in the mixed blue light) can be adjusted, to produce a mixed light having a target color coordinate.

Referring to FIG. 3, color difference among the plurality of display panels in the related splicing screen display apparatus is observed. for example. display panels 1, 3, 5, 6, and 7 exhibit a color shift toward yellow. The inventors of the present disclosure discover that the issue of color difference among the plurality of display panels can be corrected by using a light emitting substrate comprising light emitting elements of multiple types. Specifically, color coordinates of the plurality of display panels can be adjusted by adjusting driving currents provided to the light emitting elements of multiple types. to achieve substantially uniform color coordinates among the plurality of display panels. For example, light emitting substrates for the plurality of display panels in the related splicing screen display apparatus may be replaced with light emitting substrates according to the present disclosure. With respect to display panels 1, 3, 5, 6, and 7 (which exhibit a color shift toward yellow), driving currents provided to the light emitting elements of the first type can be decreased and/or driving currents provided to the light emitting elements of the second type can be increased to adjust the color coordinates of light emitted from the display panels 1, 3, 5, 6, and 7 until the color coordinates are substantially the same as color coordinates of light emitted from the display panels 2, 4, 8, and 9.

FIG. 8 is a schematic diagram illustrating the structure of a display apparatus in some embodiments according to the present disclosure. Referring to FIG. 8. the display apparatus in some embodiments includes a light emitting substrate LES. a light diffusor LD on the light emitting substrate LES, a color conversion layer CCL on a side of the light diffuser LD away from the light emitting substrate LES. a light enhancing layer LEL on a side of the color conversion layer CCL away from the light emitting substrate LES, and a display panel DP on a side of the light enhancing light LEL away from the light emitting substrate LES. In some embodiments, the display panel DP is a liquid crystal display panel. In some embodiments. the color conversion layer CCL is a quantum-dots color conversion layer including one or more quantum dots materials. Optionally, the color conversion layer CCL is a color conversion film. In some embodiments, the light enhancing layer LEL includes a dual brightness enhancement film In some embodiments, the light enhancing layer LEL includes a prism layer including a plurality of prisms. The display apparatus depicted in FIG. 8 may be a portion of a splicing screen display apparatus.

The inventors of the present disclosure discover that, surprisingly and unexpectedly, the color differences among the plurality of display panels can be reduced or obviated by using the unique light emitting substrate according to the present disclosure. In some embodiments. the light emitting substrate includes light emitting elements of multiple types. For example, the light emitting substrate includes light emitting elements of a first type and light emitting elements of a second type. Light emitted from light emitting elements of different types has a same color but different wavelength ranges. In one example, the light emitted from light emitting elements of different types has a blue color but different wavelength ranges. As used herein, the term “same color” does not imply a same wavelength or a same wavelength range.

In some embodiments, the light emitting substrate includes light emitting elements of N number of types. N being an integer equal to or greater than 2. In one example, N=2. In another example, N=3. In another example N=4.

In some embodiments, light emitting elements of a respective type of the light emitting elements of multiple types are substantially evenly distributed in the light emitting substrate. As used herein. the term “substantially evenly distributed” refers to a respective percentage of light emitting elements of the respective type in each of a plurality of areas of the light emitting substrate is substantially the same. As used herein, the term “substantially the same” refers to a difference between two values not exceeding 20% of a base value (e.g., one of the two values), e.g., not exceeding 18%, not exceeding 16%, not exceeding 14%, not exceeding 12%, not exceeding 10%, not exceeding 8%. not exceeding 6%. not exceeding 4%. not exceeding 2%, not exceeding 1%. not exceeding 0.5%, not exceeding 0.1%. not exceeding 0.05%, and not exceeding 0.01%, of the base value.

In some embodiments, each area of the plurality of areas in the light emitting substrate includes at least 10 light emitting elements, e.g., at least 15 light emitting elements, at least 20 light emitting elements, at least 25 light emitting elements. at least 30 light emitting elements, at least 35 light emitting elements. at least 40 light emitting elements, at least 45 light emitting elements, at least 50 light emitting elements, at least 55 light emitting elements, at least 60 light emitting elements, at least 65 light emitting elements, at least 70 light emitting elements, at least 75 light emitting elements, at least 80 light emitting elements, at least 85 light emitting elements, at least 90 light emitting elements, at least 95 light emitting elements, or at least 100 light emitting elements.

In some embodiments, the plurality of areas have a substantially same number of light emitting elements. In some embodiments, the plurality of areas have a substantially same size. In some embodiments, the plurality of areas have a substantially same shape.

In another example, the light emitting substrate includes light emitting elements of N number of types. N being an integer equal to or greater than 2. A percentage of light emitting elements of a n-th type in each of the plurality of areas in the light emitting substrate is substantially the same, 2≤n≤N. In some embodiments. respective percentages of light emitting elements of N number of types in each of the plurality of areas in the light emitting substrate are represented as p1, p2, . . . , pn, p(n+1) . . . pN. In one example, at least two of p1,p2, . . . , pn, p (n+1) . . . pN are different from each other. In another example, p1, p2, . . . , pn, p(n+1), . . , pN are substantially the same.

In some embodiments, the light emitting substrate includes light emitting elements of a first type and light emitting elements of a second type. In one example. a percentage of the light emitting elements of the first type in each of the plurality of areas in the light emitting substrate is in a range of 40% to 60%; and a percentage of the light emitting elements of the second type in each of the plurality of areas in the light emitting substrate is in a range of 40% to 60%. In another example. the percentage of the light emitting elements of the first type in each of the plurality of areas in the light emitting substrate is 50%. and the percentage of the light emitting elements of the second type in each of the plurality of areas in the light emitting substrate is 50%. In one example. the percentage of the light emitting elements of the first type in each of the plurality of areas in the light emitting substrate and the percentage of the light emitting elements of the second type in each of the plurality of areas in the light emitting substrate are substantially the same. In another example. the percentage of the light emitting elements of the first type in each of the plurality of areas in the light emitting substrate and the percentage of the light emitting elements of the second type in each of the plurality of areas in the light emitting substrate are different from each other.

In some embodiments, light emitting elements of the light emitting substrate are arranged in an array comprising rows and columns. In some embodiments. the light emitting elements of multiple types are alternately arranged in at least one row of the array. Optionally, the light emitting elements of multiple types are alternately arranged in each row of the array. In one example. the light emitting substrate includes light emitting elements of a first type, light emitting elements of a second type, and light emitting elements of a third type: and the light emitting elements of the first type. the light emitting elements of the second type, and the light emitting elements of the third type are alternately arranged in at least one row of the array. In another example, the light emitting substrate includes light emitting elements of a first type and light emitting elements of a second type: and the light emitting elements of the first type and the light emitting elements of the second type are alternately arranged in at least one row of the array.

In some embodiments, the light emitting elements of multiple types are alternately arranged in at least one column of the array. Optionally, the light emitting elements of multiple types are alternately arranged in each column of the array. In one example, the light emitting substrate includes light emitting elements of a first type, light emitting elements of a second type, and light emitting elements of a third type: and the light emitting elements of the first type, the light emitting elements of the second type, and the light emitting elements of the third type are alternately arranged in at least one column of the array. In another example, the light emitting substrate includes light emitting elements of a first type and light emitting elements of a second type: and the light emitting elements of the first type and the light emitting elements of the second type are alternately arranged in at least one column of the array.

In some embodiments, the light emitting elements of multiple types are alternately arranged in at least one row of the array and in at least one column of the array. Optionally, the light emitting elements of multiple types are alternately arranged in each row of the array and in each column of the array. In one example. the light emitting substrate includes light emitting elements of a first type, light emitting elements of a second type, and light emitting elements of a third type: the light emitting elements of the first type, the light emitting elements of the second type, and the light emitting elements of the third type are alternately arranged in at least one row of the array: and the light emitting elements of the first type. the light emitting elements of the second type. and the light emitting elements of the third type are alternately arranged in at least one column of the array. In another example, the light emitting substrate includes light emitting elements of a first type and light emitting elements of a second type: the light emitting elements of the first type and the light emitting elements of the second type are alternately arranged in at least one row of the array; and the light emitting elements of the first type and the light emitting elements of the second type are alternately arranged in at least one column of the array.

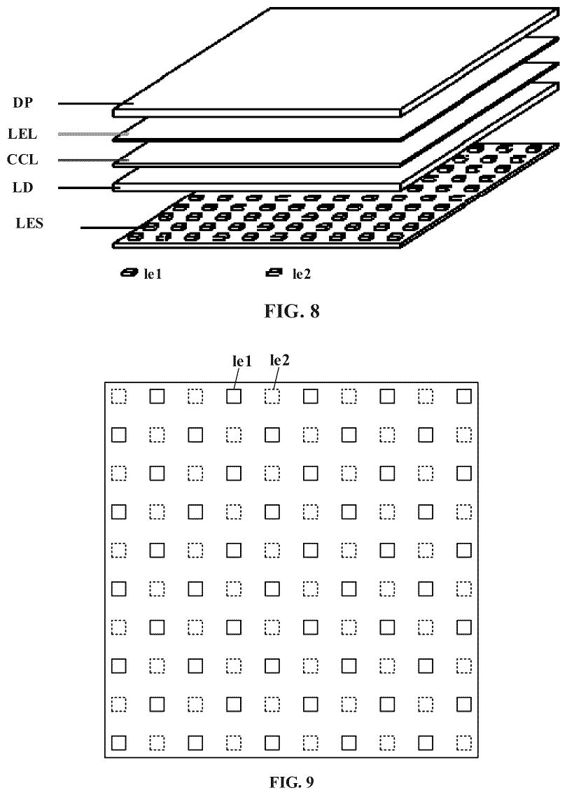

FIG. 9 is a schematic diagram illustrating the structure of a light emitting substrate in some embodiments according to the present disclosure. Referring to FIG. 9, the light emitting substrate in some embodiments includes light emitting elements of a first type le1 and light emitting elements of a second type le2. The light emitting elements of the first type le1 and the light emitting elements of the second type le2 are alternately arranged in at least one row of the array of light emitting elements. The light emitting elements of the first type le1 and the light emitting elements of the second type le2 are alternately arranged in at least one column of the array of light emitting elements. As shown in FIG. 9. the light emitting elements of the first type le1 and the light emitting elements of the second type le2 are alternately arranged in each row and each column of the array of light emitting elements. Light emitted from the light emitting elements of the first type le1 and the light emitting elements of the second type le2 has a same color but different wavelength ranges. In one example. light emitted from the light emitting elements of the first type le1 is a blue light having a wavelength in a range of 447 nm to 448 nm, and light emitted from the light emitting elements of the second type le2 is a blue light having a wavelength in a range of 452 nm to 453 nm. The inventors of the present disclosure discover that, by having the light emitting elements of multiple types substantially evenly distributed, the color differences among the plurality of display panels can be reduced or obviated.

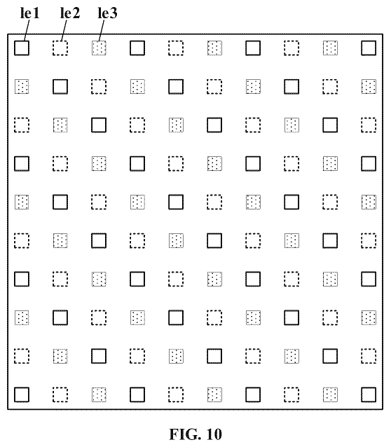

FIG. 10 is a schematic diagram illustrating the structure of a light emitting substrate in some embodiments according to the present disclosure. Referring to FIG. 10, the light emitting substrate in some embodiments includes light emitting elements of a first type le1, light emitting elements of a second type le2. and light emitting elements of a third type le3. The light emitting elements of the first type le1, the light emitting elements of the second type le2, and the light emitting elements of the third type le3 are altemately arranged in at least one row of the array of light emitting elements. The light emitting elements of the first type le1. the light emitting elements of the second type le2. and the light emitting elements of the third type le3 are alternately arranged in at least one column of the array of light emitting elements. As shown in FIG. 10, the light emitting elements of the first type le1, the light emitting elements of the second type le2, and the light emitting elements of the third type le3 are alternately arranged in each row and each column of the array of light emitting elements. Light emitted from the light emitting elements of the first type le1. the light emitting elements of the second type le2, and the light emitting elements of the third type le3 has a same color but different wavelength ranges. The inventors of the present disclosure discover that, by having the light emitting elements of multiple types substantially evenly distributed, the color differences among the plurality of display panels can be reduced or obviated.

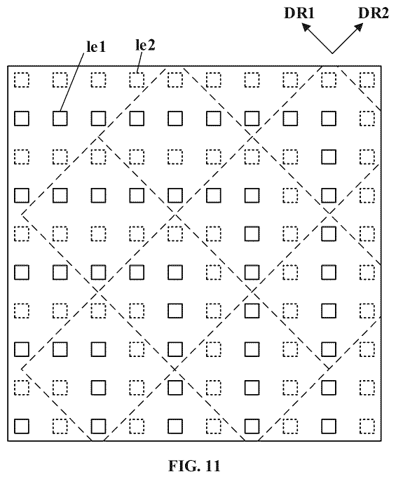

Various appropriate implementations may be practiced in the present disclosure to achieve substantially evenly distributed light emitting elements of multiple types. FIG. 11 is a schematic diagram illustrating the structure of a light emitting substrate in some embodiments according to the present disclosure. Referring to FIG. 11, the light emitting substrate in some embodiments includes light emitting elements of a first type le1 and light emitting elements of a second type le2. The light emitting elements of the first type le1 and the light emitting elements of the second type le2 are not alternately arranged in any row of the array of light emitting elements. The light emitting elements of the first type le1 and the light emitting elements of the second type le2 are not alternately arranged in any column of the array of light emitting elements. However, the light emitting elements of the first type le1 are substantially evenly distributed because a percentage of light emitting elements of the first type in each of a plurality of areas of the light emitting substrate is substantially the same: and the light emitting elements of the second type le2 are substantially evenly distributed because a percentage of light emitting elements of the second type in each of a plurality of areas of the light emitting substrate is substantially the same. FIG. 11 denotes a plurality of areas in dotted lines.

In some embodiments, the light emitting elements of multiple types are alternately arranged in diagonal lines along at least a first direction of the array. Optionally, the light emitting elements of multiple types are alternately arranged in diagonal lines along a first direction of the array, and altemately arranged in diagonal lines along a second direction of the array. Referring to FIG. 11, the light emitting elements of the first type le1 and the light emitting elements of the second type le2 are alternately arranged in diagonal lines along a first direction DR1 of the array, and are alternately arranged in diagonal lines along a second direction DR2 of the array.

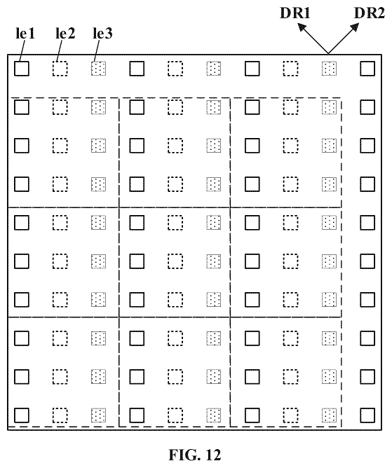

FIG. 12 is a schematic diagram illustrating the structure of a light emitting substrate in some embodiments according to the present disclosure. Referring to FIG. 12. the light emitting substrate in some embodiments includes light emitting elements of a first type le1, light emitting elements of a second type le2, and light emitting elements of a third type le3. The light emitting elements of the first type le1. the light emitting elements of the second type le2. and the light emitting elements of the third type le3 are alternately arranged in at least one row of the array of light emitting elements. The light emitting elements of the first type le1, the light emitting elements of the second type le2, and the light emitting elements of the third type le3 are not alternately arranged in any column of the array of light emitting elements. However, the light emitting elements of the first type le1 are substantially evenly distributed because a percentage of the light emitting elements of the first type le1 in each of a plurality of areas of the light emitting substrate is substantially the same. the light emitting elements of the second type le2 are substantially evenly distributed because a percentage of the light emitting elements of the second type le2 in each of a plurality of areas of the light emitting substrate is substantially the same: and the light emitting elements of the third type le3 are substantially evenly distributed because a percentage of the light emitting elements of the third type le3 in each of a plurality of areas of the light emitting substrate is substantially the same. FIG. 12 denotes a plurality of areas in dotted lines.

Referring to FIG. 12, the light emitting elements of the first type le1, the light emitting elements of the second type le2, and the light emitting elements of the third type le3 are altemately arranged in diagonal lines along a first direction DR1 of the array, and are alternately arranged in diagonal lines along a second direction DR2 of the array.

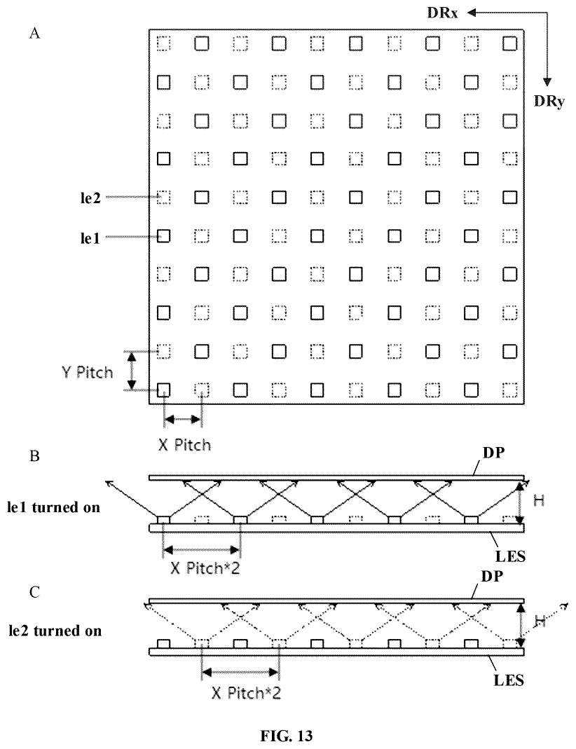

FIG. 13A is a plan view of a light emitting substrate in some embodiments according to the present disclosure. FIG. 13B is a cross-sectional view of a light emitting substrate in some embodiments according to the present disclosure. FIG. 13C is a cross-sectional view of a light emitting substrate in some embodiments according to the present disclosure. The arrangement of the light emitting elements of multiple types is similar to that depicted in FIG. 9. Along a row direction DRx. the light emitting elements have a first pitch (denoted as “X Pitch” in FIG. 13A). Along a column direction Dry. the light emitting elements have a second pitch (denoted as “Y Pitch” in FIG. 13A). Along the row direction DRx, two adjacent light emitting elements of the first type are spaced apart by twice of the first pitch (denoted as “X Pitch*2” in FIG. 13B). and two adjacent light emitting elements of the second type are spaced apart by twice of the first pitch (denoted as “X Pitch*2” in FIG. 13C).

The light emitting substrate LES is spaced apart from a display panel DP by a distance H. To ensure the display panel is free of mura, the first pitch and the distance H satisfy H/(2*(first pitch))>0.5; and the second pitch and the distance H satisfy H/(2*(second pitch))>0.5.

In another aspect. the present disclosure provides a display apparatus. In some embodiments. the display apparatus includes the light emitting substrate described herein. and a display panel configured to receive light emitted from the light emitting substrate. In some embodiments, the display apparatus further includes one or more driving circuits. In some embodiments, the one or more driving circuits are configured to adjust driving currents respectively provided to the light emitting elements of multiple types (e.g., driving currents respectively provided to the light emitting elements of the first type and to the light emitting elements of the second type). By adjusting the driving currents respectively provided to the light emitting elements of multiple types, proportions of light of multiple wavelength ranges in the mixed light (e.g., proportions of the blue light of the relatively short wavelength and the blue light of the relatively long wavelength in the mixed blue light) can be adjusted, to produce a mixed light having a target color coordinate.

In some embodiments, the display apparatus further includes a color conversion layer. In some embodiments, the color conversion layer includes a plurality of color conversion blocks configured to convert light emitted from the light emitting substrate into a light of a different color, and a plurality of light transmissive blocks configured to allow the light emitted from the light emitting substrate to transmit through without color conversion.

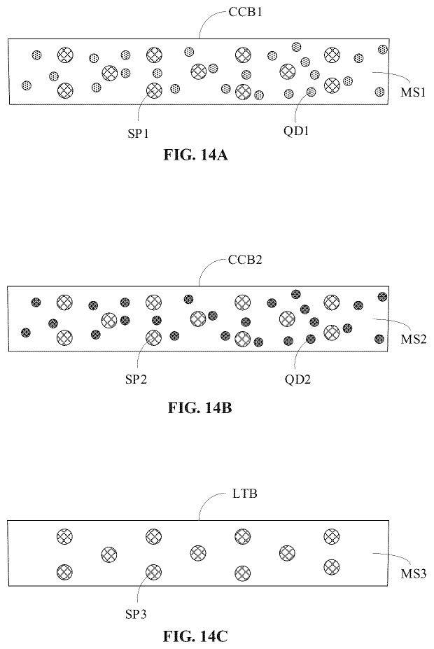

FIG. 14A is a schematic diagram illustrating the structure of a first color conversion block in some embodiments according to the present disclosure. Referring to FIG. 14A, the first color conversion block CCBI is a color conversion block configured to convert a light of a third color (e.g., a blue light) into a light of a first color (e.g., a red light). In some embodiments, the first color conversion block CCBI includes a first matrix MSI. a plurality of first scattering particles SPI and a plurality of first quantum dots QDI dispersed in the first matrix MSI. The first matrix MSI may include a polymer material such as an organic polymer material. Examples of appropriate polymer materials for making the first matrix MSI include epoxy resins, acrylic resins, polyurethane resins, silicone resins, and silane resins. Examples of appropriate materials for making the plurality of first scattering particles SPI include TiO₂, ZnO, ZrO₂, Al₂O₃, SiO₂. Examples of appropriate quantum dots materials for making the plurality of first quantum dots QDI include a quantum dots material of a first color (e.g., a red color). The quantum dots material may include a material selected from a group consisting of CdS, CdSe, ZnSe. InP. PbS, CsPbCl3, CsPbBr3, CsPhI3, CdS/ZnS, CdSe/ZnS, InP/ZnS. PbS/ZnS, CsPbCl3/ZnS. CsPbBr3/ZnS, and CsPh13/ZnS.

FIG. 14B is a schematic diagram illustrating the structure of a second color conversion block in some embodiments according to the present disclosure. Referring to FIG. 14B. the second color conversion block CCB2 is a color conversion block configured to convert a light of a third color (e.g., a blue light) into a light of a second color (e.g., a green light). In some embodiments. the second color conversion block CCB2 includes a second matrix MS2, a plurality of second scattering particles SP2 and a plurality of second quantum dots QD2 dispersed in the second matrix MS2. The second matrix MS2 may include a polymer material such as an organic polymer material. Examples of appropriate polymer materials for making the second matrix MS2 include epoxy resins, acrylic resins. polyurethane resins, silicone resins, and silane resins. Examples of appropriate materials for making the plurality of second scattering particles SP2 include TiO₂, ZnO, ZrO₂, Al₂O₃, SiO₂. Examples of appropriate quantum dots materials for making the plurality of second quantum dots QD2 include a quantum dots material of a second color (e.g., a green color). The quantum dots material may include a material selected from a group consisting of CdS, CdSe, ZnSe, InP. PbS, CsPbCl3, CsPbBr3, CsPhI3, CdS/ZnS, CdSe/ZnS, InP/ZnS, PbS/ZnS, CsPbCl3/ZnS, CsPbBr3/ZnS, and CsPh13/ZnS.

FIG. 14C is a schematic diagram illustrating the structure of a light transmissive block in some embodiments according to the present disclosure. Referring to FIG. 14C. the light transmissive block LTB in some embodiments includes a third matrix MS3 and a plurality of third scattering particles SP3 dispersed in the third matrix MS3. The third matrix MS3 may include a polymer material such as an organic polymer material. Examples of appropriate polymer materials for making the third matrix MS3 include epoxy resins, acrylic resins, polyurethane resins, silicone resins, and silane resins. Examples of appropriate materials for making the plurality of third scattering particles SP3 include TiO₂, ZnO, ZrO₃, Al₂O₃, SiO₂.

In one example, the first matrix MSI, the second matrix MS2. and the third matrix MS3 includes a same polymer material. In another example, at least two of the first matrix MS1, the second matrix MS2, and the third matrix MS3 includes different polymer materials.

In one example. the first scattering particles SPI. the second scattering particles SP2, and the third scattering particles SP3 includes a same scattering material. In another example. at least two of the first scattering particles SP1, the second scattering particles SP2, and the third scattering particles SP3 includes different scattering materials.

In some embodiments, referring to FIG. 8, the display apparatus further includes a light diffusor LD on the light emitting substrate LES. In some embodiments, the display apparatus further includes a light enhancing layer LEL on a side of the color conversion layer CCL away from the light emitting substrate LES.

In another aspect. the present disclosure provides a splicing screen display apparatus. In some embodiments, the splicing screen display apparatus includes a plurality of display units. The plurality of display units include a plurality of display panels. and a plurality of light emitting substrates configured to provide light to the plurality of display panels. A respective display unit of the plurality of display units includes a respective display panel of the plurality of display panels and a respective light emitting substrate of the plurality of light emitting substrates. Optionally, the plurality of display panels are spliced together to display an image.

In some embodiments, the plurality of display units further include a plurality of color conversion layers configured to convert light emitted from the plurality of light emitting substrates. A respective display unit of the plurality of display units includes a respective color conversion layer of the plurality of color conversion layers. In some embodiments, the respective color conversion layer includes a plurality of color conversion blocks configured to convert light emitted from the light emitting substrate into a light of a different color, and a plurality of light transmissive blocks configured to allow the light emitted from the light emitting substrate to transmit through without color conversion.

In some embodiments, the respective display unit further includes a light diffusor on the respective light emitting substrate. In some embodiments. the respective display unit further includes a light enhancing layer on a side of the respective color conversion layer away from the light emitting substrate.

In some embodiments. the respective display unit includes the respective light emitting substrate (e.g., the light emitting substrate described herein), and the respective display panel configured to receive light emitted from the respective light emitting substrate. In some embodiments, the respective display unit further includes one or more driving circuits. In some embodiments, the one or more driving circuits are configured to adjust driving currents respectively provided to the light emitting elements of multiple types (e.g., driving currents respectively provided to the light emitting elements of the first type and to the light emitting elements of the second type). By adjusting the driving currents respectively provided to the light emitting elements of multiple types, proportions of light of multiple wavelength ranges in the mixed light (e.g., proportions of the blue light of the relatively short wavelength and the blue light of the relatively long wavelength in the mixed blue light) can be adjusted, to produce a mixed light having a target color coordinate.

In some embodiments, the one or more driving circuits are configured to independently adjust driving currents. with respect to each type of the multiple types, provided to the light emitting elements of multiple types. For example, first driving currents provided to the light emitting elements of the first type and second driving currents provided to the light emitting elements of the second type are independently adjusted by the one or more driving circuits

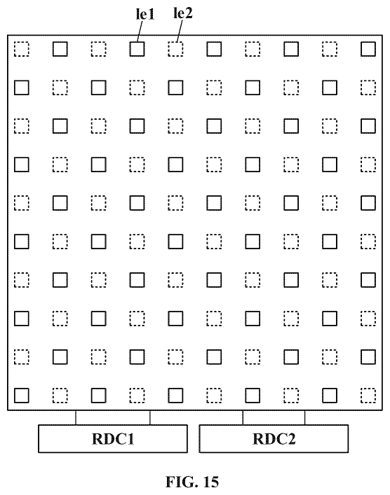

In some embodiments, the one or more driving circuits includes driving circuits of multiple types respectively connected to the light emitting elements of multiple types. A respective driving circuit of a respective type is configured to adjust driving currents provided to light emitting elements of a respective type. FIG. 15 is a schematic diagram illustrating the structure of a respective display unit in some embodiments according to the present disclosure. Referring to FIG. 15, the one or more driving circuits in some embodiments includes a respective first driving circuit RDC1 and a respective second driving circuit RDC2. The respective first driving circuit RDCI is connected to the light emitting elements of the first type le1. and is configured to adjust driving currents of the light emitting elements of the first type le1. The respective second driving circuit RDC2 is connected to the light emitting elements of the second type le2. and is configured to adjust driving currents of the light emitting elements of the second type le2.

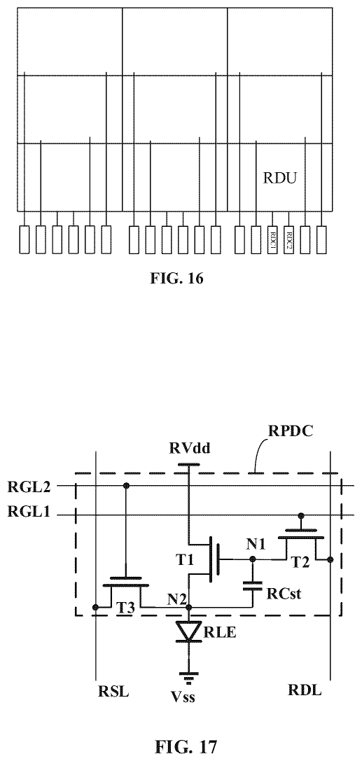

FIG. 16 is a schematic diagram illustrating the structure of a splicing screen display apparatus in some embodiments according to the present disclosure. Referring to FIG. 16, the plurality of display units in some embodiments includes driving circuits of multiple types. A respective display unit RDU includes a respective driving circuit of each type. As shown in FIG. 16, the respective display unit RDU in some embodiments includes a respective first driving circuit RDCI and a respective second driving circuit RDC2. Optionally, driving currents in each of the plurality of display units can be independently adjusted, and a color coordinate of light emitted from each of the plurality of display units can be independently adjusted. By independently adjusting color coordinates of light emitted from the plurality of display units, a substantially uniform color coordinate can be achieved throughout the plurality of display units.

Various appropriate light emitting elements may be used in the present light emitting substrate and display apparatus. Examples of appropriate light emitting elements include mini light emitting diodes, organic light emitting diodes, quantum dots light emitting diodes. and micro light emitting diodes. Optionally, the light emitting element is mini light emitting diode.

Various appropriate pixel driving circuits may be used in the present light emitting substrate and display apparatus. Examples of appropriate driving circuits include 3TIC, 2TIC. 4TIC, 4T2C, 5T2C, 6TIC, 7TIC, 7T2C. 8TIC, and 8T2C. In some embodiments, the respective one of the plurality of pixel driving circuits is a 3TIC driving circuit

FIG. 17 is a circuit diagram illustrating the structure of a respective pixel driving circuit in some embodiments according to the present disclosure. Referring to FIG. 17, the respective pixel driving circuit RPDC is connected to a respective light emitting element RLE. In some embodiments, the respective pixel driving circuit RPDC includes a respective storage capacitor RCst having a first capacitor electrode coupled to a first node N1 and a second capacitor electrode coupled to a second node N2: a driving transistor T1 having a first electrode coupled to a respective voltage supply line RVdd. a second electrode coupled to the second node N2. and a gate electrode coupled to the first node NI; a switching transistor T2 having a first electrode coupled to a respective data line RDL, a second electrode coupled to the first node NI, and a gate electrode coupled to a respective first gate line RGLI; and a sensing transistor T3 having a first electrode coupled to the respective sensing line RSL. a second electrode coupled to the second node N2, and a gate electrode coupled to a respective second gate line RGL2. The first node NI is coupled to the gate electrode of the driving transistor T1, the second electrode of the switching transistor T2. and the first capacitor electrode of the respective storage capacitor RCst. The second node N2 is coupled to the second electrode of the driving transistor T1. the second electrode of the sensing transistor T3, the second capacitor electrode of the respective storage capacitor RCst, and an anode of a respective light emitting element RLE.

In another aspect, the present disclosure provides a method of operating a display apparatus comprising the light emitting substrate described herein and a display panel configured to receive light emitted from the light emitting substrate. In some embodiments, the light emitting substrate includes light emitting elements of multiple types Light emitting elements of a respective type of the light emitting elements of multiple types are substantially evenly distributed in the light emitting substrate. In some embodiments, the method includes adjusting driving currents respectively provided to the light emitting elements of multiple types. Optionally, the method further includes driving the light emitting elements of different types to emit light of a same color but different wavelength ranges. Optionally, the method includes driving the light emitting elements of different types to emit light of a blue color but different wavelength ranges.

In some embodiments, the display apparatus further includes a color conversion layer. In some embodiments, the method further includes converting light emitted from the light emitting substrate into a light of a different color by a plurality of color conversion blocks of the color conversion layer: and allowing the light emitted from the light emitting substrate to transmit through a plurality of light transmissive blocks without color conversion.

In another aspect, the present disclosure provides a method of operating a splicing screen display apparatus comprising a plurality of display units. In some embodiments, the plurality of display units include a plurality of display panels. and a plurality of light emitting substrates. Optionally, a respective display unit of the plurality of display units comprises a respective display panel of the plurality of display panels and a respective light emitting substrate of the plurality of light emitting substrates. In some embodiments, the method includes providing light by the plurality of light emitting substrates to the plurality of display panels: and displaying an image in the plurality of display panels spliced together.

In some embodiments, the method further includes adjusting driving currents respectively provided to the light emitting elements of multiple types. Optionally, the method includes independently adjusting driving currents, with respect to each type of the multiple types, provided to the light emitting elements of multiple types.

In some embodiments. the method further includes independently adjusting driving currents in each of the plurality of display units by the driving circuits of multiple types: and independently adjusting a color coordinate of light emitted from each of the plurality of display units by the driving circuits of multiple types.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application. thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A light emitting substrate, comprising light emitting elements of multiple types;
wherein the light emitting elements of different types are configured to emit light of a same color but different wavelength ranges; and
light emitting elements of a respective type of the light emitting elements of multiple types are substantially evenly distributed in the light emitting substrate.

2. The light emitting substrate of claim 1, wherein the light emitting elements of different types are configured to emit light of a blue color but different wavelength ranges.

3. The light emitting substrate of claim 1, wherein the light emitting elements of the light emitting substrate are arranged in an array comprising rows and columns; and
the light emitting elements of multiple types are alternately arranged in at least one row of the array.

4. The light emitting substrate of claim 1, wherein a respective percentage of light emitting elements of the respective type in each of a plurality of areas of the light emitting substrate is substantially the same; and
each area of the plurality of areas in the light emitting substrate includes at least 10 light emitting elements.

5. The light emitting substrate of claim 4, wherein the light emitting elements of multiple types are alternately arranged in each row of the array.

6. The light emitting substrate of claim 1, wherein the light emitting elements of the light emitting substrate are arranged in an array comprising rows and columns; and
the light emitting elements of multiple types are alternately arranged in at least one column of the array.

7. The light emitting substrate of claim 6, wherein the light emitting elements of multiple types are alternately arranged in each column of the array.

8. The light emitting substrate of claim 1, wherein the light emitting elements of the light emitting substrate are arranged in an array comprising rows and columns; and
the light emitting elements of multiple types are alternately arranged in at least one row of the array and in at least one column of the array.

9. The light emitting substrate of claim 8, wherein the light emitting elements of multiple types are alternately arranged in each row of the array and in each column of the array.

10. The light emitting substrate of claim 1, wherein the light emitting substrate comprises light emitting elements of N number of types, N being an integer equal to or greater than 2; and
a percentage of light emitting elements of a n-th type in each of a plurality of areas in the light emitting substrate is substantially the same, 2≤n≤N.

11. The light emitting substrate of claim 1, wherein the light emitting substrate comprises light emitting elements of a first type and light emitting elements of a second type;
wherein the light emitting elements of the first type and the light emitting elements of the second type are configured to emit a blue light.

12. The light emitting substrate of claim 11, wherein the light emitting elements of the first type are configured to emit a blue light having a wavelength in a range of 447 nm to 448 nm; and
the light emitting elements of the second type are configured to emit a blue light having a wavelength in a range of 452 nm to 453 nm.

13. A display apparatus, comprising the light emitting substrate of claim 1, and a display panel configured to receive light emitted from the light emitting substrate.

14. The display apparatus of claim 13, further comprising a color conversion layer;
wherein the color conversion layer comprises:
a plurality of color conversion blocks configured to convert light emitted from the light emitting substrate into a light of a different color; and
a plurality of light transmissive blocks configured to allow the light emitted from the light emitting substrate to transmit through without color conversion.

15. The display apparatus of claim 13, further comprising one or more driving circuits configured to adjust driving currents respectively provided to the light emitting elements of multiple types.

16. A splicing screen display apparatus, comprising a plurality of display units;
wherein the plurality of display units comprise a plurality of display panels, and a plurality of light emitting substrates configured to provide light to the plurality of display panels;
a respective display unit of the plurality of display units comprises a respective display panel of the plurality of display panels and a respective light emitting substrate of the plurality of light emitting substrates; and
the plurality of display panels are spliced together to display an image;
wherein the respective light emitting substrate comprises light emitting elements of multiple types;
wherein the light emitting elements of different types are configured to emit light of a same color but different wavelength ranges; and
light emitting elements of a respective type of the light emitting elements of multiple types are substantially evenly distributed in the light emitting substrate.

17. The splicing screen display apparatus of claim 16, wherein the plurality of display units further include a plurality of color conversion layers configured to convert light emitted from the plurality of light emitting substrates;
a respective display unit of the plurality of display units comprises a respective color conversion layer of the plurality of color conversion layers;
the respective color conversion layer comprises:
a plurality of color conversion blocks configured to convert a light emitted from the light emitting substrate into a light of a different color; and
a plurality of light transmissive blocks configured to allow the light emitted from the light emitting substrate to transmit through without color conversion.

18. The splicing screen display apparatus of claim 16, wherein the respective display unit further comprises one or more driving circuits configured to adjust driving currents respectively provided to the light emitting elements of multiple types; and
the one or more driving circuits are configured to independently adjust driving currents, with respect to each type of the multiple types, provided to the light emitting elements of multiple types.

19. The splicing screen display apparatus of claim 16, wherein the plurality of display units comprise driving circuits of multiple types;
a respective display unit comprises a respective driving circuit of each type;
driving currents in each of the plurality of display units are independently adjustable by the driving circuits of multiple types; and
a color coordinate of light emitted from each of the plurality of display units are independently adjustable by the driving circuits of multiple types.

20. A method of operating a display apparatus comprising a light emitting substrate and a display panel configured to receive light emitted from the light emitting substrate;
wherein the light emitting substrate includes light emitting elements of multiple types; and
light emitting elements of a respective type of the light emitting elements of multiple types are substantially evenly distributed in the light emitting substrate;
wherein the method comprises to adjust driving currents respectively provided to the light emitting elements of multiple types; and
driving the light emitting elements of different types to emit light of a same color but different wavelength ranges.
